(19) United States
(12) Patent Application Publication
(10) Pub. No.: US 2016/0091957 A1
(43) Pub. Date: Mar. 31, 2016

(54) POWER MANAGEMENT FOR MEMORY ACCESSES IN A SYSTEM-ON-CHIP

(71) Applicants: Suketu R. Partiwala, Chandler, AZ (US); Vasudev Bibikar, Austin, TX (US); Stefan Macher, Fuerth (DE); Verma R. Rohit, Fremont, CA (US); Philip Abraham, Beaverton, OR (US); Irwin J. Vaz, Campbell, CA (US); Manan Kathuria, Allentown, PA (US)

(72) Inventors: Suketu R. Partiwala, Chandler, AZ (US); Vasudev Bibikar, Austin, TX (US); Stefan Macher, Fuerth (DE); Verma R. Rohit, Fremont, CA (US); Philip Abraham, Beaverton, OR (US); Irwin J. Vaz, Campbell, CA (US); Manan Kathuria, Allentown, PA (US)

(21) Appl. No.: 14/498,516

(22) Filed: Sep. 26, 2014

(51) Int. Cl. G06F 1/32; G11C 7/10

(52) U.S. Cl. CPC G06F 1/3275; G06F 1/3243; G11C 7/1072

(57) ABSTRACT

Techniques and mechanisms to manage power states for a system-on-chip (SOC). Multiple modules of the SOC include a first module to perform a task including one or more accesses to a memory. In an embodiment, the SOC is transitioned to one of a path-to-memory-available (PMA) power state and a path-to-memory-not-available (PMNA) power state, where the transition is in response to an indication that, of the multiple modules, only the first module is to access the memory during the task. The PMA power state enables data communication between the memory and the first module and prevents data communication between the memory and any other module of the multiple modules. In another embodiment, the PMNA power state prevents data communication between the memory and any of the multiple modules, but allows a low latency transition from the PMNA power state to the PMA power state.

### BACKGROUND

1. Technical Field

Embodiments discussed herein generally relate to power management for an integrated circuit. More particularly, certain embodiments include, but are not limited to, a power state that facilitates power efficient access to a memory of a system-on-chip.

2. Background Art

In a system-on-chip (SOC), circuit components of the SOC are integrated on a single chip. SOC integrated circuits are becoming ever more popular in various applications including embedded applications such as with set-top-boxes, mobile phones, portable media devices, and so on. While the high integration of components in a SOC provides advantages such as chip area savings and better signal quality, power consumption and performance latency are becoming increasingly important constraints for devices that include such SOCs. Especially with portable SOC applications, efficient power management functionality is a valuable aspect of many SOC implementations.

Memory accesses have a significant effect on SOC efficiency and performance. Often, different components of a SOC variously access the same memory resources. Existing SOC memory access solutions variously involve powering up an entire SOC, and a main voltage supply for the SOC, when an access to a memory of the SOC is needed. However, there is a huge cost associated with such approaches at least in terms of latency and transitional energy. Moreover, there are challenges associated with the sharing of memory between components of a SOC, such as latency requirements for operation of components, power efficiency in accessing memory, and the like.

### BRIEF DESCRIPTION OF THE DRAWINGS

The various embodiments of the present invention are illustrated by way of example, and not by way of limitation, in the figures of the accompanying drawings and in which:

FIG. 1 is a high-level functional block diagram illustrating elements of a system-on-chip to provide memory access according to an embodiment.

FIG. 2 is a flow diagram illustrating elements of a method for operating a system-on-chip according to an embodiment.

FIG. 3 is a state diagram illustrating power state transitions of a system-on-chip according to an embodiment.

FIG. 4 is a timing diagram illustrating elements of a signal exchange to operate a system-on-chip according to an embodiment.

FIG. 5 is a timing diagram illustrating elements of a task performed by a system-on-chip according to an embodiment.

FIG. 6 is a high-level functional block diagram illustrating elements of a computer platform to provide access to memory resources according to an embodiment.

FIG. 7 is a high-level functional block diagram illustrating elements of a mobile device to provide access to memory resources according to an embodiment.

### DETAILED DESCRIPTION

As the level of integration in SOC circuitry increases, the number and variety of SOC components that utilize memory resources also grows. Consequently, there is a growing need to provide power efficient memory access to SOC components. Techniques and mechanisms discussed herein variously provide power states that facilitate efficient access to a memory by a particular module of multiple modules that reside in a SOC. Such techniques and/or mechanisms may provide for a first SOC power state wherein access to the memory is provided to a first SOC module, but not to one or more other SOC modules that might otherwise have access to the memory in a different power state of the SOC. The power states may further comprise a second power state that prevents access to the memory by the first module as well as the other modules. However, the second power state may serve as a standby power state that facilitates low latency transition to the first power state.

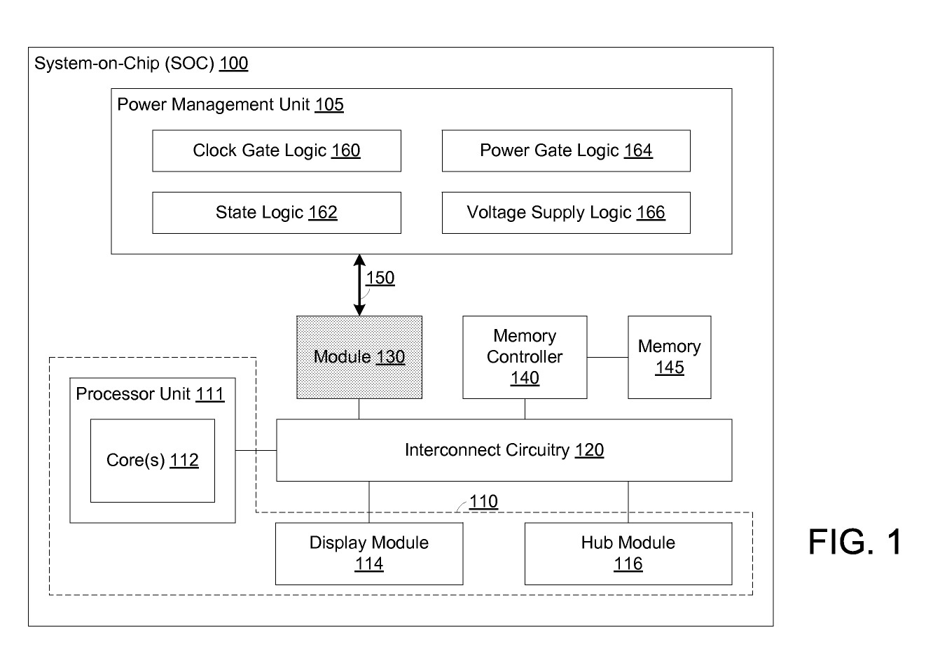

FIG. 1 illustrates elements of a system-on-chip (SoC) 100 to provide power management for memory accesses according to certain embodiments. SOC 100 is merely one example of an integrated circuit (IC) that comprises multiple components (referred to herein as “modules”) each to variously access the same memory resources that are included in or coupled to that IC. Such an IC may provide one or more SOC power states that, with respect to availability of the memory to the multiple modules, support memory access to only some—e.g., only one—of the multiple modules.

Certain embodiments are discussed herein with respect to power states that facilitate memory access by a module 130 of SOC 100, where such power states prevent memory access by one or more other modules 110 of SOC 100. However, such discussion may be extended to additionally or alternatively apply to memory access by any of the variety of other modules of a SOC. The particular number and types of the one or more other modules 110 are merely illustrative, and not limiting on certain embodiments

SOC 100 may include circuitry to operate as a component of a desktop computer, laptop computer, handheld device (e.g., a smart phone, palmtop device, tablet, etc.), gaming console, wireless communication device or other such computing-capable device. To facilitate such operation, SOC 100 may comprise multiple modules—e.g., including module 130 and one or more modules 110—and a memory controller 140 coupled thereto, the memory controller 140 to provide the multiple modules with access to a memory that is included in or coupled to SOC 100. By way of illustration and not limitation, a memory controller 140 may provide access to a memory 145, such as a dynamic random access memory (DRAM) module, that is included in SOC 100. In another embodiment, memory 145 is part of another IC chip (not shown) that may be stacked with SOC 100 in an IC die stack of a packaged device. Operation of memory 145 and/or memory controller 140 may conform, for example, to some or all requirements of a dual data rate (DDR) specification such as the DDR4 SDRAM JEDEC Standard JESD79-4, September, 2012, a high bandwidth memory (HBM) specification such as the HBM DRAM Standard JESD235, October 2013, or other such specification.

Interconnect circuitry 120 may couple various modules of SOC 100 to memory controller 140—and in some embodiments, to one another—for various exchanges of data and/or control messages. Interconnect circuitry 120 may include any of a variety of combinations of one or more busses, crossbars, fabrics and/or other connection mechanisms to variously couple modules 110, 130 to memory controller 140. Interconnect circuitry 120 may comprise one or more address and/or data busses, for example. It should be understood that some or all of modules 110, 130 may each be coupled to memory controller 140 via a distinct communication path. For example, one or more dedicated data and/or control lines, etc. may be used to couple only a particular one of modules 110, 130 to memory 145, according to some embodiments. Communication between modules 110, 130 and memory controller 140 may be adapted from conventional communication techniques, which are not detailed herein and are not limiting on certain embodiments.

Modules 110, 130 may variously send to memory controller 140 requests to access memory 145—e.g., wherein modules 110, 130 request such access independent of one another. Although certain embodiments or not limited in this regard, the one or more modules 110 may include a processor unit 111 coupled to memory controller 140. Processor unit 111 may include one or more cores 112 to execute an operating system (OS), not shown. In addition, processor unit 111 may include a cache memory (not shown), such as, for example, static random access memory (SRAM) and the like, or any of a variety of types of internal integrated memory. In one example, memory 145 may store a software program that may be executed by processor unit 111. In some embodiments, processor unit 111 may have access to Basic Input/Output System (BIOS) instructions—e.g. stored in memory 145 or in a separate storage device.

One or more modules 110 may include additional or alternative modules, as represented by the illustrative display module 114 to perform image data processing and hub module 116 to serve as a hub for of one or more other components (not shown) of SOC 100. Hub module 116 may comprise a platform hub, an input/output (I/O) hub or other such hub circuitry, for example. Similar to processor unit 111, display module 114 and hub module 116 may each access memory 145 at various times via memory controller 140—e.g., depending on a given power state of SOC 100.

SOC 100 may operate at different times in any of two or more power states, and may provide logic—e.g., including hardware, firmware and/or executing software—to support, initiate, or otherwise implement transitions between such power states. According to one exemplary embodiment, a power management unit 105 of SOC 100 may comprise state logic 162 including hardware and/or executing software to identify a given power state to be configured for SOC 100—e.g., where such identifying is based in part on current and/or expected future operation of modules 110, 130. Furthermore, power management unit 105 may include or couple to circuitry to variously configure different power states identified at different times by state logic 162. By way of illustration and not limitation, power management unit 105 may include clock gate logic 160 comprising circuitry to perform clock gating of one or more components of SOC 100 to variously configure power state of SOC 100. Alternatively or in addition, power management unit 105 may include power gate logic 164 to perform power gating for configuring such power state. In some embodiments, voltage supply logic 166 may selectively activate or deactivate one or more supply voltages to implement a given power state. The particular mechanisms by which such clock gating, power gating and/or voltage regulation are to be implemented may be adapted from conventional power control mechanisms, which are not detailed herein to avoid obscuring features of certain embodiments.

In one embodiment, one or more power states configured with power management unit 105 are to selectively make communication with memory 145 possible for a subset—e.g., only the subset—of modules 110, 130. A first power state may enable data communication between memory module 130 and memory 145 via memory controller 140, where that first power state also prevents some or all of the one or more modules 110 from participating in data exchanges with memory 145. In some embodiments, a second power state serves as a standby mode that allows for quick transition to the first power state for accessibility of memory 145 by module 130. Such power states may provide improved power efficiency in accommodating a task of module 130 that is considered critical to operation of SOC 100 or is otherwise to be performed during a period of time when one or more modules 110 are expected to be inactive at least with respect to memory accesses.

For example, module 130 may provide functionality for I/O communications between SOC 100 and an agent (not shown) coupled thereto. Such an agent may reside on a platform that includes SOC 100 or, alternatively, may be in communication with such a platform via any of a variety of combinations of one or more wired networks and/or wireless networks. In an embodiment, module 130 comprises a communication processor, modem, WiFi network module, Bluetooth network module, cellular telephony module or other such communication I/O interface hardware. In some embodiments, module 130 comprises a global positioning system (GPS) module, a global navigation satellite system (GNSS) module or other receiver and/or transmitter circuitry to exchange geodetic information. In still other embodiments, module 130 comprises streaming circuitry for SOC 100 to output or receive a stream of audio data. These are just some examples of functionality provided by module 130 to perform a task comprising memory accesses—e.g., while the one or more other modules 110 are in relatively deep low power modes.

In order to efficiently support operation of module 130 while one or more modules 110 are inactive (at least with respect to accessing memory 145), power management unit 105 may implement a power state to selectively disable data communication between memory 145 and the one or more modules 110. Moreover, power management unit 105 may selectively implement another power state for additional power efficiency while module 130 is not accessing memory 145, but may be expected to imminently access memory 145 during activity of the one or more modules 110. Such power states may be variously implemented in response to signaling 150 exchanged between module 150 and power management unit 105. In some embodiments, module 130 is the only one of modules 110, 130 that is capable of requesting or otherwise signaling to power management unit 105 that such power states are to be implemented. Signaling 150 may provide fast operation of control circuitry that implements power state transitions independent of executing firmware (or other such code).

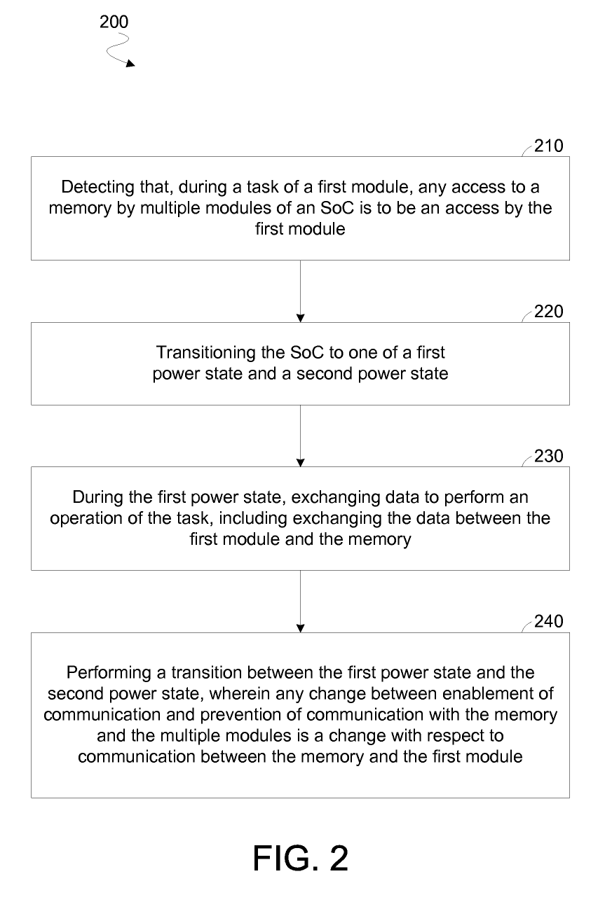

FIG. 2 illustrates elements of the method 200 for operating a SOC according to an embodiment. Method 200 may be performed to variously configure power states of SOC 100, for example. In an embodiment, method 200 is performed with circuitry having some or all of the features of power management unit 105.

Method 200 may include, at 210, detecting that, during a task of a first module of multiple modules of the SOC, any access to a memory by the multiple modules of the SOC is to be an access by the first module. The first module may have some or all of the features of module 130—e.g., wherein the multiple modules are coupled to memory 145 via a memory controller 140. The detecting at 210 may be based on one or more signals, received by power management unit 105 for example, indicating current activity of the multiple modules and/or expected future activity of the multiple modules. Such one or more signals may specify or otherwise indicate that, of the multiple modules, only the first module is expected to require memory access for at least a period of time that allows for a disabling of memory access (with attendant power savings) for the one or more others of the multiple modules. The particular number and/or type of such one or more signals, which may be received as a priori input, are not limiting on certain embodiments. The particular mechanisms by which such one or more signals might be generated, communicated and/or evaluated may be adapted from conventional platform performance evaluation techniques, which are not detailed herein.

In response to the detecting at 210, method 200 may, at 220, transition the SOC to one of a first power state and a second power state, wherein the first power state enables data communication between the memory and the first module and prevents data communication between the memory and any of the multiple modules other than the first module. For brevity, such a first power state is referred to herein as a path-to-memory-available (PMA) power state. By contrast, the second power state may prevent data communication between the memory and any of the multiple modules. However, the second power state may allow for a quick transition to the first power state—e.g., as compared to any corresponding transition that might be provided by another power state of the SOC. Accordingly, the second power state may facilitate rapid resumption of memory accesses by the first module in the first power state. For brevity, such a second power state is referred to herein as a path-to-memory-not-available (PMNA) power state.

During the first power state, method 200 may, at 230, exchange data to perform an operation of the task for the first module. The exchanging at 230 may include exchanging the data between the first module and the memory via a memory controller of the SOC. Prior to or after the exchange of data at 230, method 200 may, at 240, perform a transition of the SOC between the first power state and the second power state. Any change, due to the transition at 240, between an enablement of data communication with the memory and the multiple modules and a prevention of data communication with the memory and the multiple modules is a change with respect to communication between the memory and the first module. Accordingly, the first module may be the only one of the multiple modules that, due to the transition performed at 240, is transitioned between being prevented from exchanging data with the memory and being allowed to exchange data with the memory. By contrast, the other modules may each remain incapable of communicating with the memory prior to, during and after the transition at 240.

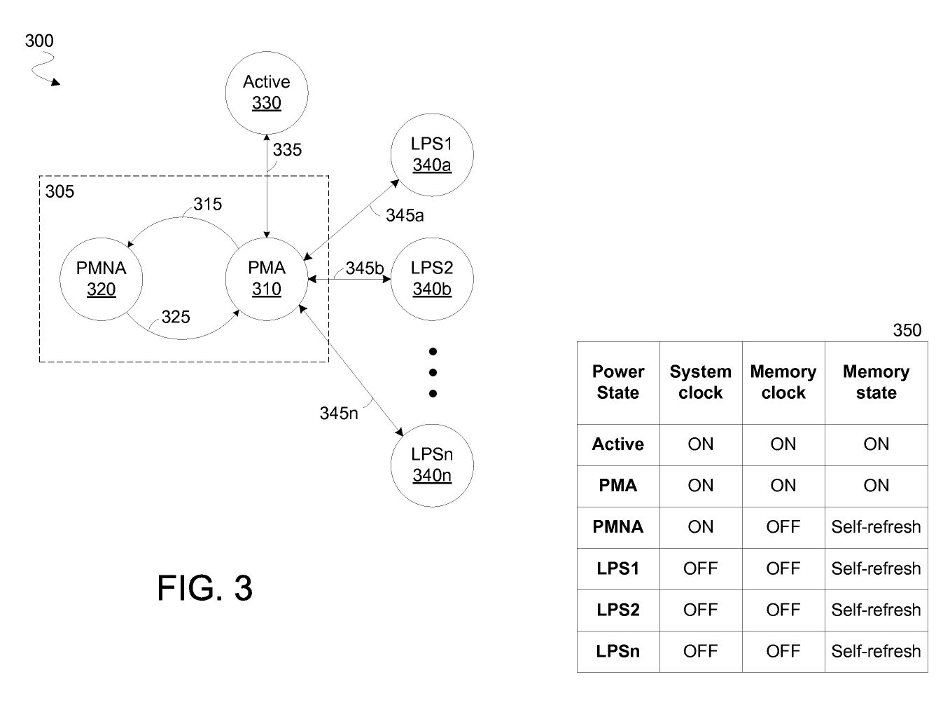

The transitioning at 220 may include transitioning the SOC from a power state of the SOC other than either of the first power state and the second power state. For example, FIG. 3 shows a state diagram 300 including power states and power state transitions for a SOC such as one operated according to method 200. As illustrated in stage diagram 300, a state map 305 according to one embodiment (the state map 305 including a path-to-memory-available power state PMA 310 and a path-to-memory-not-available power state PMNA 320) may be part of a larger state map that includes one or more other power states of the SOC. State map 305 includes a transition 315 from PMA 310 to PMNA 320. Such a transition 315 may occur in response to power management logic of the SOC detecting an opportunity to at least temporarily reduce power consumption (in addition to other power savings provided by PMA 320) before an expected imminent memory access by the first module. State map 305 further comprises a transition 325 from PMNA 320 to PMA 310 that, for example, may occur in response to the first module indicating a need for such a next memory access—e.g., while inactivity of the other modules is expected to persist.

State diagram 300 and table 350 of FIG. 3 illustrate certain distinctions between PMA 310 and/or PMNA 320 with respect to various conventional power states. However, a reader of ordinary skill in the technology will appreciate that the states and state transitions of timing diagram 300 that are outside of state map 305 are merely illustrative, and are not limiting on certain embodiments. In an embodiment, state diagram 300 further comprises, outside of state map 305, a transition 335 from PMA 310 to a fully operational power state Active 330. While in Active 330, the SOC may support memory access by any and each of the SOCs multiple modules. State diagram 300 further shows various low-power states LPS1 340a, LPS2 340b, . . . , LPSn 340n outside of state map 305, wherein such low power states may variously transition to/from PMA 310 via respective transitions 345a, 345b, . . . , 345n. Some or all such low power states may treat the multiple modules equally at least with respect to supporting access to the memory by the multiple modules. Although certain embodiments are not limited in this regard, LPS1 340a, LPS2 340b, . . . , LPSn 340n may include any of various conventional standby, sleep, hibernate and/or other power states. Examples of such conventional power states include, for example, the SOi1, SOi2, . . . etc. power states for SOCs manufactured by Intel Corporation of Santa Clara, Calif., USA.

As shown in table 350, low power states LPS1 340a, LPS2 340b, . . . , 340b may variously include disabling the memory itself to prevent any data exchanges—e.g., wherein the memory device is decoupled, powered down, clock gated, power gated, and/or the like. As shown in the illustrative table 350, such disabling may include placing the memory in a self-refresh mode that, for example, prevents data exchanges between the memory and the memory controller. By contrast, the memory is enabled during PMA 310 to facilitate data exchanges with the first module, and (in some embodiments) may even be so enabled during PMNA 320—e.g., wherein some other component of the SOC is instead configured in PMNA 320 to prevent such data exchanges.

In an embodiment, the memory itself is partially disabled during PMNA 320—e.g., by placing the memory in a self-refresh mode and/or by gating, preventing or otherwise limiting the communication of a memory clock signal to the memory. During a PMA state, the memory may be instead be configured to receive an explicit memory refresh signal from the memory controller—e.g., rather than operate in a self-refresh mode. For example, as shown in table 350, a memory clock signal may be provided to the memory during a PMA power state, wherein the memory clock signal is prevented from being provided to the memory during a PMNA power state.

Alternatively or in addition, a system clock signal may be communicated to the first module (but not other modules of the SOC) during PMA 310—and in some embodiments during PMNA 320—but not to the first module or the other modules during one or more other, low power states of the SOC. Accordingly, a transition between the PMA power state and the PMNA power state—e.g. one of transitions 315, 325—may comprise changing a power gating and/or clock gating to one or more of the first module, the memory controller or the memory. Where the memory, memory controller and/or first module remain at least partially powered and/or clocked during PMNA 320, some or all such components of the SOC may be readily available for an “instant on” implementation of transition 325 by resuming clock signaling to such components.

In some embodiments, a module of the SOC other than the first module may be coupled to a power rail during an operational power state (other than a PMA power state), wherein that module is clock gated, power gated and/or decoupled from the power rail during the PMA state and/or the PMNA power state. For example, each of the multiple modules may be coupled to receive power via a respective power rail during Active 330, wherein of the multiple modules, only the first module is coupled to receive sufficient power during PMA 320 to enable memory accesses. The first module may also be the only one of the multiple modules coupled to such power during PMNA 320.

In some embodiments, the memory controller is coupled to receive power during a PMA power state and may, in some embodiments, be coupled to receive at least some power during a PMNA power state. For example, the memory controller may be power gated and/or clock gated during PMNA 320. Alternatively or in addition, a PMA power state may include interconnect circuitry being decoupled and/or powered down to prevent data communication between the memory controller and the one or more modules of the SOC other than the first module. In such an embodiment, a PMNA power state may include other interconnect circuitry being decoupled and/or powered down to further prevent data communications between the memory controller and the first module.

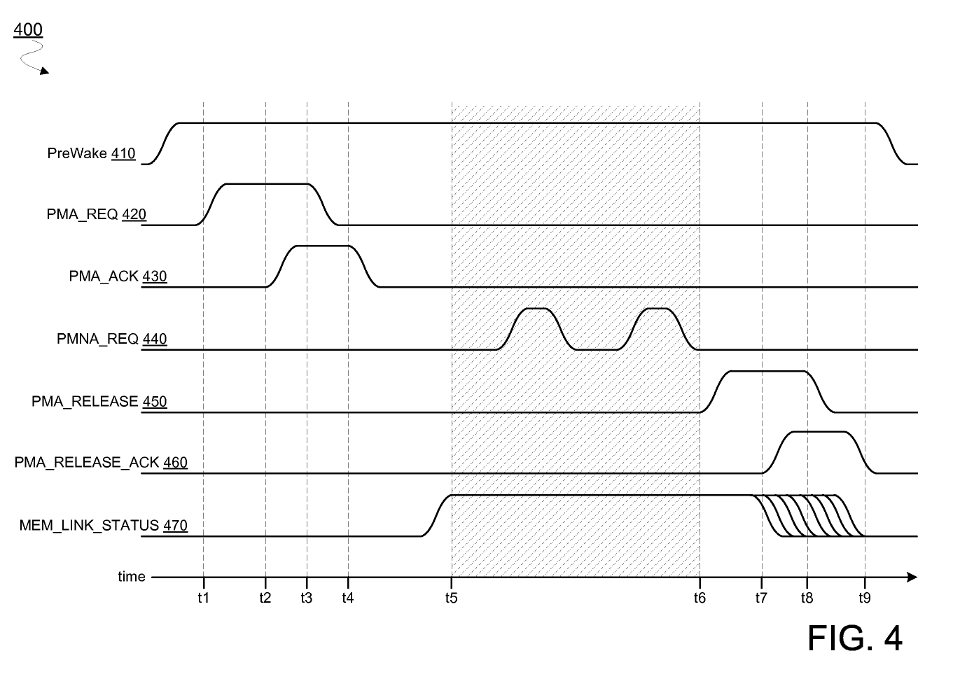

Referring now to FIG. 4, a timing diagram 400 is shown for signals exchanged between a module of a SOC and power management logic for the SOC. The module may be selectively provided with access to a memory by a PMA power state of the SOC. Timing diagram 400 may represent an exchange—such as that of signals 150, for example—to control one or more transitions each to a PMA power state or a PMNA power state. For example, such one or more power state transitions may include one or both of transitions 315, 325. The particular timing of signals shown in timing diagram 400 are not limiting on certain embodiments.

As shown in the illustrative timing diagram 400, a signal PreWake 410 may be asserted by the module, where PreWake 410 signals to the power management logic in advance that a request for a PMA power mode is to be expected. In response to PreWake 410, one or more clock signal sources of the SOC may be started up—e.g. for the SOC to transition from a low power state such as one of LPS1 340a, LPS2 340b, . . . , LPSn 340n.

At a time t1, a signal PMA_REQ 420 may be asserted by the module to request that the power management logic configure a PMA power state. Subsequently, the power management logic may assert a signal PMA_ACK 430 acknowledging back to the module the request communicated by PMA_REQ 420. The request signal PMA_REQ 420 may be subsequently deasserted—e.g., after a rising edge of PMA_ACK 430 is received by the module.

In response to the PMA power state request, MEM_LINK_STATUS 470 may be asserted by the power management logic to signal to the module that a link is available for the module to exchange data with the memory. In response, the module may access the memory via the link—e.g. during the illustrative period between a time t5 and a time t6. During this time period, a signal PMNA_REQ 440 may be asserted by the module one or more times to variously request that the power management logic configure a PMNA power state. Such assertion of PMNA_REQ 440 may be made in anticipation of an upcoming period of inactivity by the module (at least with respect to memory accesses). The SOC may transition between the PMA power state and the PMNA power state multiple times during streaming and/or other operations of a task that access this memory.

When the task is complete, the module may assert a signal PMA_RELEASE 450 to indicate to the power management unit that (at least temporarily) the module no longer requires the memory and, in some cases, that a latency due to an expected future link-up procedure is acceptable. The module may then assert a signal PMA_RELEASE_ACK 460—e.g., during deassertion of MEM_LINK_STATUS 470—acknowledging back to the power management logic the receipt of PMA_RELEASE 450. After MEM_LINK_STATUS 470 indicates that the memory has been released, PreWake 410 may be deasserted to signal to the power management unit that the PMA power state will not be needed—e.g., where the SOC is to transition to a low power state.

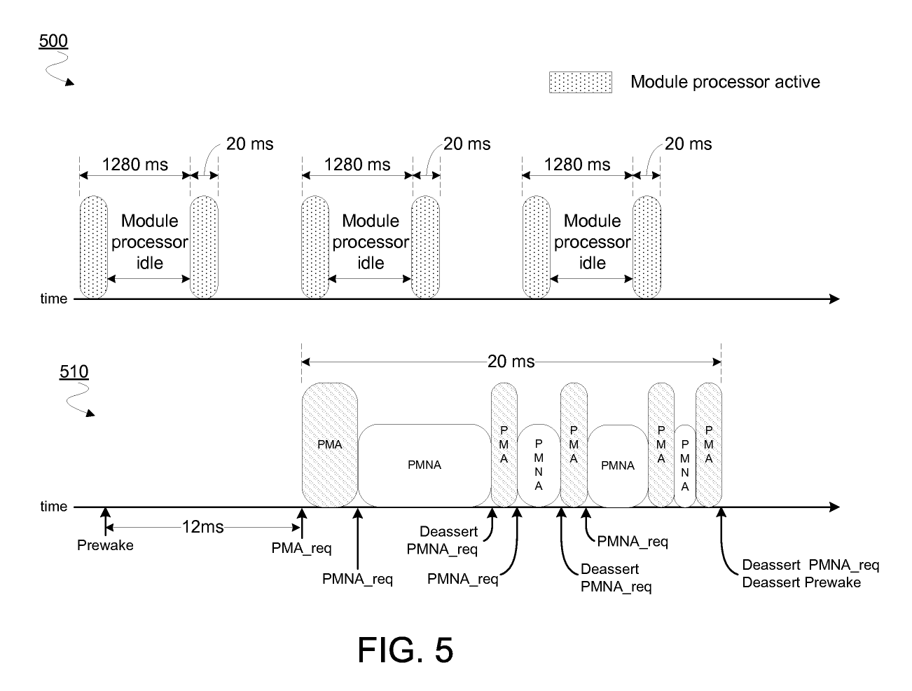

Referring now to FIG. 5, timing diagrams 500, 510 are shown to illustrate operation of an SOC, wherein such operation includes various power state transitions according to an embodiment. Timing diagrams 500, 510 may represent operation of an SOC including some or all of the features of SOC 100, for example. In an embodiment, one or more of the power transitions shown in FIG. 5 are performed according to operations of method 200.

Timing diagrams 500, 510 represent features of memory paging operations that, for example, may be performed in support of third Generation (3G) communications such as those according to an International Mobile Telecommunications-2000 (IMT-2000) specification of the International Telecommunication Union of Geneva, Switzerland. However, features of timing diagram 500, 510 may similarly apply to any of a variety of one or more additional or alternative operations, according to different embodiments.

As shown in timing diagram 500, a module of the SOC—in this example, a modem—wakes up every periodically (e.g., every 1280 milliseconds) to implement any necessary paging operations that require access to a main memory of the SOC. A typical paging cycle may last for ˜20 ms, although certain embodiments are not limited in this regard. In an embodiment, the modem may include a communication processor, controller, state machine or other circuitry that is active for only some periods of the illustrative 20 ms paging cycle. For example, a processor of the modem may need access to the memory for only about 10% of the cycle. However, when it needs access to the memory, the processor may be unable to tolerate a high latency in transitioning to a power state that accommodates such access.

As shown in timing diagram 510, when a processor (or other circuitry) of the modem is active, it may assert a PMA_req signal to configure the SOC in a PMA power state. During such a PMA power state, the modem processor may be able to access the main memory with very low latency. When the modem's processor enters an idle state (with respect to memory accesses), the modem may assert a PMNA_req signal to transition the SOC into a PMNA power state. Configuration of the PMNA power state may prevent the modem from being able to access the main memory. However, the PMNA power state may employ additional power savings measures in addition to those of the PMA power state. By way of illustration and not limitation, configuration of the PMNA power state may include putting the memory in a self-refresh mode and/or disabling one or more phase locked loops (PLLs) that otherwise facilitate clock signaling. During a single 20 ms paging cycle, the SOC may transition multiple times between the PMA power state and the PMNA power state.

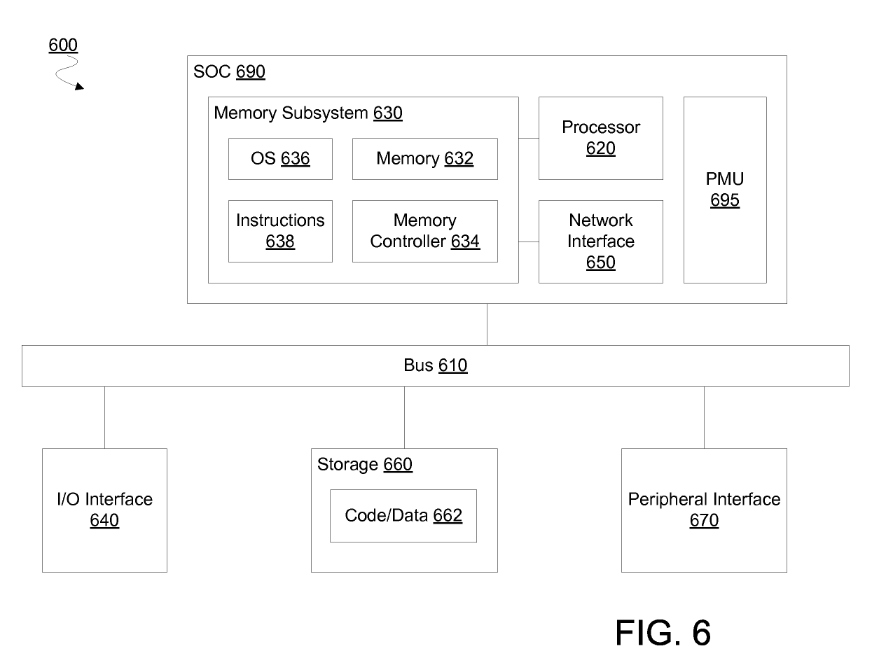

FIG. 6 is a block diagram of an embodiment of a computing system in which power management of a SOC may be implemented. System 600 represents a computing device in accordance with any embodiment described herein, and may be a laptop computer, a desktop computer, a server, a gaming or entertainment control system, a scanner, copier, printer, or other electronic device. System 600 may include processor 620, which provides processing, operation management, and execution of instructions for system 600. Processor 620 may include any type of microprocessor, central processing unit (CPU), processing core, or other processing hardware to provide processing for system 600. Processor 620 controls the overall operation of system 600, and may be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 630 represents the main memory of system 600, and provides temporary storage for code to be executed by processor 620, or data values to be used in executing a routine. Memory subsystem 630 may include one or more memory devices such as read-only memory (ROM), flash memory, one or more varieties of random access memory (RAM), or other memory devices, or a combination of such devices. Memory subsystem 630 stores and hosts, among other things, operating system (OS) 636 to provide a software platform for execution of instructions in system 600. Additionally, other instructions 638 are stored and executed from memory subsystem 630 to provide the logic and the processing of system 600. OS 636 and instructions 638 are executed by processor 620.

Memory subsystem 630 may include memory device 632 where it stores data, instructions, programs, or other items. In one embodiment, memory subsystem 630 resides on a SOC 690 of system 600, and includes a memory controller 634 to provide access to memory 632 for modules that also reside on SOC 690. SOC 690 may include some or all of the features of SOC 100. Such modules of SOC 690 may include, for example, processor 620, network interface 650 and/or any of a variety of other such components of system 600. A power management unit PMU 695 of SOC 690 may variously configure power states of the SOC, according to techniques discussed herein.

SOC 610 is coupled to bus/bus system 610. Bus 610 is an abstraction that represents any one or more separate physical buses, communication lines/interfaces, and/or point-to-point connections, connected by appropriate bridges, adapters, and/or controllers. Therefore, bus 610 may include, for example, one or more of a system bus, a Peripheral Component Interconnect (PCI) bus, an industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 610 may also correspond to interfaces in network interface 650.

System 600 may also include one or more input/output (I/O) interface(s) 640, one or more internal mass storage device(s) 660, and peripheral interface 670 coupled to bus 610. I/O interface 640 may include one or more interface components through which a user interacts with system 600 (e.g., video, audio, and/or alphanumeric interfacing). Network interface 650 provides system 600 the ability to communicate with remote devices (e.g., servers, other computing devices) over one or more networks. Network interface 650 may include an Ethernet adapter, wireless interconnection components, USB (universal serial bus), or other wired or wireless standards-based or proprietary interfaces.

Storage 660 may be or include any conventional medium for storing large amounts of data in a nonvolatile manner, such as one or more magnetic, solid state, or optical based disks, or a combination. Storage 660 holds code or instructions and data 662 in a persistent state (i.e., the value is retained despite interruption of power to system 600). Storage 660 may be generically considered to be a “memory,” although memory 630 is the executing or operating memory to provide instructions to processor 620. Whereas storage 660 is nonvolatile, memory 630 may include volatile memory (i.e., the value or state of the data is indeterminate if power is interrupted to system 600).

Peripheral interface 670 may include any hardware interface not specifically mentioned above. Peripherals refer generally to devices that connect dependently to system 600. A dependent connection is one where system 600 provides the software and/or hardware platform on which operation executes, and with which a user interacts.

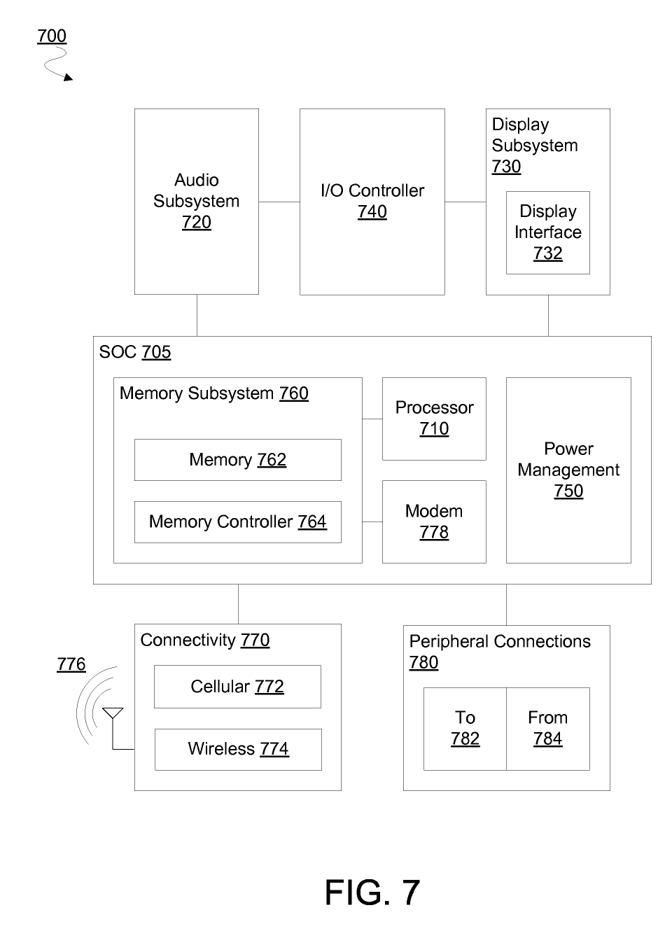

FIG. 7 is a block diagram of an embodiment of a mobile device in which power management of a SOC may be implemented. Device 700 represents a mobile computing device, such as a computing tablet, a mobile phone or smartphone, a wireless-enabled e-reader, or other mobile device. It will be understood that certain of the components are shown generally, and not all components of such a device are shown in device 700.

Device 700 may include processor 710, which performs the primary processing operations of device 700. Processor 710 may include one or more physical devices, such as microprocessors, application processors, microcontrollers, programmable logic devices, or other processing means. The processing operations performed by processor 710 include the execution of an operating platform or operating system on which applications and/or device functions are executed. The processing operations include operations related to I/O (input/output) with a human user or with other devices, operations related to power management, and/or operations related to connecting device 700 to another device. The processing operations may also include operations related to audio I/O and/or display I/O.

In one embodiment, device 700 includes audio subsystem 720, which represents hardware (e.g., audio hardware and audio circuits) and software (e.g., drivers, codecs) components associated with providing audio functions to the computing device. Audio functions may include speaker and/or headphone output, as well as microphone input. Devices for such functions may be integrated into device 700, or connected to device 700. In one embodiment, a user interacts with device 700 by providing audio commands that are received and processed by processor 710.

Display subsystem 730 represents hardware (e.g., display devices) and software (e.g., drivers) components that provide a visual and/or tactile display for a user to interact with the computing device. Display subsystem 730 may include display interface 732, which may include the particular screen or hardware device used to provide a display to a user. In one embodiment, display interface 732 includes logic separate from processor 710 to perform at least some processing related to the display. In one embodiment, display subsystem 730 includes a touchscreen device that provides both output and input to a user.

I/O controller 740 represents hardware devices and software components related to interaction with a user. I/O controller 740 may operate to manage hardware that is part of audio subsystem 720 and/or display subsystem 730. Additionally, I/O controller 740 illustrates a connection point for additional devices that connect to device 700 through which a user might interact with the system. For example, devices that may be attached to device 700 might include microphone devices, speaker or stereo systems, video systems or other display device, keyboard or keypad devices, or other I/O devices for use with specific applications such as card readers or other devices.

As mentioned above, I/O controller 740 may interact with audio subsystem 720 and/or display subsystem 730. For example, input through a microphone or other audio device may provide input or commands for one or more applications or functions of device 700. Additionally, audio output may be provided instead of or in addition to display output. In another example, if display subsystem includes a touchscreen, the display device also acts as an input device, which may be at least partially managed by I/O controller 740. There may also be additional buttons or switches on device 700 to provide I/O functions managed by I/O controller 740.

In one embodiment, I/O controller 740 manages devices such as accelerometers, cameras, light sensors or other environmental sensors, gyroscopes, global positioning system (GPS), or other hardware that may be included in device 700. The input may be part of direct user interaction, as well as providing environmental input to the system to influence its operations (such as filtering for noise, adjusting displays for brightness detection, applying a flash for a camera, or other features).

In one embodiment, device 700 includes power management 750 that manages battery power usage, charging of the battery, and features related to power saving operation. Memory subsystem 760 may include memory device(s) 762 for storing information in device 700. Memory subsystem 760 may include nonvolatile (state does not change if power to the memory device is interrupted) and/or volatile (state is indeterminate if power to the memory device is interrupted) memory devices. Memory 760 may store application data, user data, music, photos, documents, or other data, as well as system data (whether long-term or temporary) related to the execution of the applications and functions of system 700.

In one embodiment, memory subsystem 760 includes memory controller 764 (which could also be considered part of the control of system 700). Device 700 may include a SOC 705 comprising memory controller 764 and one or more modules (e.g., including processor 700, a modem 778 and/or the like) that are to variously access memory 762 via memory controller 764. SOC 705 may include some or all of the features of SOC 100. Power management 750 may variously configure different power states of SOC 705 at different times, wherein the power states include a PMA power state and a PMNA power state as discussed herein.

Connectivity 770 may include hardware devices (e.g., wireless and/or wired connectors and communication hardware) and software components (e.g., drivers, protocol stacks) to enable device 700 to communicate with external devices. The device could be separate devices, such as other computing devices, wireless access points or base stations, as well as peripherals such as headsets, printers, or other devices.

Connectivity 770 may include multiple different types of connectivity. To generalize, device 700 is illustrated with cellular connectivity 772 and wireless connectivity 774—e.g., via the illustrative dipole antenna 776. Cellular connectivity 772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 774 refers to wireless connectivity that is not cellular, and may include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 780 include hardware interfaces and connectors, as well as software components (e.g., drivers, protocol stacks) to make peripheral connections. It will be understood that device 700 could both be a peripheral device (“to” 782) to other computing devices, as well as have peripheral devices (“from” 784) connected to it. Device 700 commonly has a “docking” connector to connect to other computing devices for purposes such as managing (e.g., downloading and/or uploading, changing, synchronizing) content on device 700. Additionally, a docking connector may allow device 700 to connect to certain peripherals that allow device 700 to control content output, for example, to audiovisual or other systems.

In addition to a proprietary docking connector or other proprietary connection hardware, device 700 may make peripheral connections 780 via common or standards-based connectors. Common types may include a Universal Serial Bus (USB) connector (which may include any of a number of different hardware interfaces), DisplayPort including MiniDisplayPort (MDP), High Definition Multimedia Interface (HDMI), Firewire, or other type.

In one implementation, a SOC circuit comprises multiple modules including a first module, the multiple modules each comprising respective circuitry configured to request access to a memory, a memory controller coupled to each of the multiple modules, and a power management unit comprising circuitry configured to receive one or more signals indicating that, during a task of the first module, any access to the memory by the multiple modules is to be an access by the first module. In response to the one or more signal, the power management unit is to transition the SOC circuit to one of a first power state and a second power state, wherein the first power state enables data communication between the memory and the first module and prevents data communication between the memory and any module of the multiple modules other than the first module. The first module is to exchange data to perform an operation of the task, including the first module to exchange the data with the memory via a memory controller, and the power management unit is further to perform a transition between the first power state and the second power state, wherein any change, due to the transition, between an enablement of communication between the memory and the multiple modules and a prevention of communication between the memory and the multiple modules is a change with respect to communication between the memory and the first module.

In an embodiment, wherein the SOC includes the memory. In another embodiment, a memory clock signal is provided to the memory during the first power state, and the memory clock signal is prevented from being provided to the memory during the second power state. In another embodiment, a clock signal is provided to the first module during the first power state and during the second power state. In another embodiment, one of the multiple modules other than the first module is coupled to a power rail during a power state of the system-on-chip other than the first power state and the second power state, and the one of the multiple modules is decoupled from the power rail during one of the first power state and the second power state.

In another embodiment, each of the multiple modules is coupled to receive power via a respective power rail during an active power state other than the first power state and the second power state, and wherein, of the multiple modules, only the first module is coupled to receive power via a respective power rail during the first power state. In another embodiment, of the multiple modules, only the first module is coupled to receive power via the respective power rail during the second power state. In another embodiment, the memory controller is coupled to receive power during the first power state. In another embodiment, the memory controller is coupled to receive power during the second power state.

In another embodiment, of the multiple modules, only the first module includes circuitry coupled to request one of the first power state and the second power state. In another embodiment, during the first power state, the memory is configured to receive a memory refresh signal from the memory controller. In another embodiment, performing the transition between the first power state and the second power state includes changing a power gating the first module, the memory controller or the memory. In another embodiment, performing the transition between the first power state and the second power state includes changing a clock gating of the first module, the memory controller or the memory.

In another implementation, a computer-readable storage medium has stored thereon instructions which, when executed by one or more processing units, cause the one or more processing units to perform a method comprising receiving one or more signals indicating that, during a task of a first module of multiple modules of a system-on-chip (SOC), any access to a memory by the multiple modules is to be an access by the first module, and in response to the one or more signals, transitioning to one of a first power state of the SOC and a second power state of the SOC, wherein the first power state enables data communication between the memory and the first module and prevents data communication between the memory and any module of the multiple modules other than the first module. The method further comprises, during the first power state, exchanging data to perform an operation of the task, including exchanging the data between the first module and the memory via a memory controller of the SOC. The method further comprises performing a transition between the first power state and the second power state, wherein any change, due to the transition, between an enablement of communication between the memory and the multiple modules and a prevention of communication between the memory and the multiple modules is a change with respect to communication between the memory and the first module.

In an embodiment, wherein the SOC includes the memory. In another embodiment, wherein a memory clock signal is provided to the memory during the first power state, and wherein the memory clock signal is prevented from being provided to the memory during the second power state. In another embodiment, wherein a clock signal is provided to the first module during the first power state and during the second power state.

In another implementation, a method comprises receiving one or more signals indicating that, during a task of a first module of multiple modules of a system-on-chip (SOC), any access to a memory by the multiple modules is to be an access by the first module, and in response to the one or more signals, transitioning to one of a first power state of the SOC and a second power state of the SOC, wherein the first power state enables data communication between the memory and the first module and prevents data communication between the memory and any module of the multiple modules other than the first module. The method further comprises, during the first power state, exchanging data to perform an operation of the task, including exchanging the data between the first module and the memory via a memory controller of the SOC. The method further comprises performing a transition between the first power state and the second power state, wherein any change, due to the transition, between an enablement of communication between the memory and the multiple modules and a prevention of communication between the memory and the multiple modules is a change with respect to communication between the memory and the first module.

In an embodiment, a memory clock signal is provided to the memory during the first power state, and the memory clock signal is prevented from being provided to the memory during the second power state. In another embodiment, a clock signal is provided to the first module during the first power state and during the second power state. In another embodiment, one of the multiple modules other than the first module is coupled to a power rail during a power state of the SOC other than the first power state and the second power state, and the one of the multiple modules is decoupled from the power rail during one of the first power state and the second power state. In another embodiment, each of the multiple modules is coupled to receive power via a respective power rail during an active power state other than the first power state and the second power state, and, of the multiple modules, only the first module is coupled to receive power via a respective power rail during the first power state.

In another implementation, a system comprises a system-on-chip (SOC) circuit including multiple modules including a first module, the multiple modules each comprising respective circuitry configured to request access to a memory, a memory controller coupled to each of the multiple modules, and a power management unit comprising circuitry configured to receive one or more signals indicating that, during a task of the first module, any access to the memory by the multiple modules is to be an access by the first module. In response to the one or more signal, the power management unit is to transition the SOC circuit to one of a first power state and a second power state, wherein the first power state enables data communication between the memory and the first module and prevents data communication between the memory and any module of the multiple modules other than the first module. The first module is to exchange data to perform an operation of the task, including the first module to exchange the data with the memory via a memory controller. The power management unit is further to perform a transition between the first power state and the second power state, wherein any change, due to the transition, between an enablement of communication between the memory and the multiple modules and a prevention of communication between the memory and the multiple modules is a change with respect to communication between the memory and the first module. The system further comprises a dipole antenna to exchange wireless communications based on operation of the SOC circuit. In an embodiment, the SOC includes the memory. In another embodiment, of the multiple modules, only the first module includes circuitry coupled to request one of the first power state and the second power state.

Techniques and architectures for managing power of system-on-chip circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A system-on-chip (SOC) circuit comprising:
multiple modules including a first module, the multiple modules each comprising respective circuitry configured to request access to a memory;
a memory controller coupled to each of the multiple modules; and
a power management unit comprising circuitry configured to receive one or more signals indicating that, during a task of the first module, any access to the memory by the multiple modules is to be an access by the first module, wherein in response to the one or more signal, the power management unit to transition the SOC circuit to one of a first power state and a second power state, wherein the first power state enables data communication between the memory and the first module and prevents data communication between the memory and any module of the multiple modules other than the first module;
wherein the first module to exchange data to perform an operation of the task, including the first module to exchange the data with the memory via a memory controller, and wherein the power management unit further to perform a transition between the first power state and the second power state, wherein any change, due to the transition, between an enablement of communication between the memory and the multiple modules and a prevention of communication between the memory and the multiple modules is a change with respect to communication between the memory and the first module.

2. The SOC circuit of claim 1, wherein the SOC includes the memory.

3. The SOC circuit of claim 1, wherein a memory clock signal is provided to the memory during the first power state, and wherein the memory clock signal is prevented from being provided to the memory during the second power state.

4. The SOC circuit of claim 1, wherein a clock signal is provided to the first module during the first power state and during the second power state.

5. The SOC circuit of claim 1, wherein one of the multiple modules other than the first module is coupled to a power rail during a power state of the system-on-chip other than the first power state and the second power state, and wherein the one of the multiple modules is decoupled from the power rail during one of the first power state and the second power state.

6. The SOC circuit of claim 1, wherein each of the multiple modules is coupled to receive power via a respective power rail during an active power state other than the first power state and the second power state, and wherein, of the multiple modules, only the first module is coupled to receive power via a respective power rail during the first power state.

7. The SOC circuit of claim 6, wherein, of the multiple modules, only the first module is coupled to receive power via the respective power rail during the second power state.

8. The SOC circuit of claim 6, wherein the memory controller is coupled to receive power during the first power state.

9. The SOC circuit of claim 8, wherein the memory controller is coupled to receive power during the second power state.

10. The SOC circuit of claim 1, wherein, of the multiple modules, only the first module includes circuitry coupled to request one of the first power state and the second power state.

11. The SOC circuit of claim 1, wherein, during the first power state, the memory is configured to receive a memory refresh signal from the memory controller.

12. The SOC circuit of claim 1, wherein performing the transition between the first power state and the second power state includes changing a power gating the first module, the memory controller or the memory.

13. The SOC circuit of claim 1, wherein performing the transition between the first power state and the second power state includes changing a clock gating of the first module, the memory controller or the memory.

14. A method comprising:
receiving one or more signals indicating that, during a task of a first module of multiple modules of a system-on-chip (SOC), any access to a memory by the multiple modules is to be an access by the first module;
in response to the one or more signals, transitioning to one of a first power state of the SOC and a second power state of the SOC, wherein the first power state enables data communication between the memory and the first module and prevents data communication between the memory and any module of the multiple modules other than the first module;
during the first power state, exchanging data to perform an operation of the task, including exchanging the data between the first module and the memory via a memory controller of the SOC; and
performing a transition between the first power state and the second power state, wherein any change, due to the transition, between an enablement of communication between the memory and the multiple modules and a prevention of communication between the memory and the multiple modules is a change with respect to communication between the memory and the first module.

15. The method of claim 14, wherein a memory clock signal is provided to the memory during the first power state, and wherein the memory clock signal is prevented from being provided to the memory during the second power state.

16. The method of claim 14, wherein a clock signal is provided to the first module during the first power state and during the second power state.

17. The method of claim 14, wherein one of the multiple modules other than the first module is coupled to a power rail during a power state of the SOC other than the first power state and the second power state, and wherein the one of the multiple modules is decoupled from the power rail during one of the first power state and the second power state.

18. The method of claim 14, wherein each of the multiple modules is coupled to receive power via a respective power rail during an active power state other than the first power state and the second power state, and wherein, of the multiple modules, only the first module is coupled to receive power via a respective power rail during the first power state.

19. A system comprising:
a system-on-chip (SOC) circuit including:
multiple modules including a first module, the multiple modules each comprising respective circuitry configured to request access to a memory;
a memory controller coupled to each of the multiple modules; and
a power management unit comprising circuitry configured to receive one or more signals indicating that, during a task of the first module, any access to the memory by the multiple modules is to be an access by the first module, wherein in response to the one or more signal, the power management unit to transition the SOC circuit to one of a first power state and a second power state, wherein the first power state enables data communication between the memory and the first module and prevents data communication between the memory and any module of the multiple modules other than the first module;
wherein the first module to exchange data to perform an operation of the task, including the first module to exchange the data with the memory via a memory controller, and wherein the power management unit further to perform a transition between the first power state and the second power state, wherein any change, due to the transition, between an enablement of communication between the memory and the multiple modules and a prevention of communication between the memory and the multiple modules is a change with respect to communication between the memory and the first module; and
a dipole antenna to exchange wireless communications based on operation of the SOC circuit.

20. The system of claim 19, wherein the SOC includes the memory.

21. The system of claim 19, wherein, of the multiple modules, only the first module includes circuitry coupled to request one of the first power state and the second power state.
